(19) United States
(12) Patent Application Publication
(10) Pub. No.: US 2019/0012025 A1
(43) Pub. Date: Jan. 10, 2019

(54) Touch Screen, Display Panel, and Display Device

(71) Applicants: BOE Technology Group Co., Ltd., Beijing (CN); Hefei Xinsheng Optoelectronics Technology Co., Ltd., Hefei (CN)

(72) Inventors: Yu Zhu, Beijing (CN); Ming Zhang, Beijing (CN); Ming Hu, Beijing (CN); Xiaodong Xie, Beijing (CN); Jian Tian, Beijing (CN); Xinbin Tian, Beijing (CN); Shifeng Xu, Beijing (CN); Qitao Zheng, Beijing (CN); Chunjian Liu, Beijing (CN)

(73) Assignees: BOE Technology Group Co., Ltd., Beijing (CN); Hefei Xinsheng Optoelectronics Technology Co., Ltd ., Hefei (CN)

(21) Appl. No.: 15/745,006

(22) PCT Filed: Jul. 5, 2017
(86) PCT No.: PCT/CN2017/091827

§ 371 Date: Jan. 15, 2018

(30) Foreign Application Priority Data
Aug. 25, 2016 (CN) 201620945343.X

(51) Int. Cl. G06F 3/041; G06F 3/044

(52) U.S. Cl. CPC G06F 3/0412; G03F 7/0007; G06F 2203/04107; G06F 3/044

(57) ABSTRACT

A touch screen, including a base substrate, and further including a first light blocking layer, a touch layer and a second light blocking layer, wherein the touch layer is disposed on a central area of the base substrate; the first light blocking layer is a black light blocking layer, and disposed on a periphery area of the base substrate, the first light blocking layer is contiguous with the touch layer and an orthographic projection of the first light blocking layer on the base substrate does not overlap an orthographic projection of the touch layer on the base substrate; and the second light blocking layer is disposed on the touch layer and is contiguous with the first light blocking layer.

### TECHNICAL FIELD

Embodiments of the present disclosure relate a touch screen, a display panel and a display device.

### BACKGROUND

ESD (Electrostatic Discharge) refers to electrostatic charge transfer between objects with different electrostatic potentials due to direct contact or electrostatic induction. When the electrostatic field reaches a certain level of energy, the electrostatic discharge can break down the medium during discharge. Due to the instantaneousness, high voltage and other characteristics of the electrostatic discharge, it is easy to break down an insulating layer of an electronic product to result in a product failure, which is an issue to be considered in the design of the touch screen and also a serious impact on the product yield. Therefore, it is possible to significantly improve product yield and reduce costs by increasing anti-ESD capability.

Through analysis on many touch screens in which ESD occurs, it is found that the ESD often happens in a region of a black matrix (BM) where the BM overlaps with the pattern at a border of a visual area (VA) of the touch screens. The region of the BM where the edge of the VA of the touch screen overlaps the pattern is broken down by electrostatic, and a conductive path is formed in the material of the BM. As a result, the analog-digital conversion value of the touch screen will be high or a short circuit occurs between the Rx and Tx, causing static electricity failure, which seriously affects performance of the touch screen and reduces product yield

### SUMMARY

At least one embodiment of the present disclosure provides a touch screen, comprising a base substrate, and further comprising a first light blocking layer, a touch layer and a second light blocking layer, wherein:
the first light blocking layer is a black light blocking layer, and disposed at an edge of the base substrate;
the touch layer is disposed on the base substrate, and the touch layer is in contact with an inner edge of the first light blocking layer and does not overlap with each other; and
the second light blocking layer is disposed on the touch layer, and the second light blocking layer is in contact with the inner edge of the first light blocking layer.

In the touch screen, as the touch layer and the first light blocking layer are disposed on the base substrate, the touch layer is contact with an inner edge of the first light blocking layer and does not overlap with each other, the second light blocking layer is disposed on the touch layer, and the second light blocking layer is in contact with the inner edge of the first light blocking layer, it is ensured that there is no first light blocking layer formed under the edge of patter of the touch layer, thereby avoiding formation of an electrostatic path in electrostatic test due to the breakdown of the first light blocking layer. Thus, electrostatic discharge is avoided.

So, there is no first light blocking layer is formed in a region where a border of the touch screen overlaps the pattern, and an electrostatic path cannot be formed in electrostatic test, thereby avoiding electrostatic discharge.

In one embodiment of the present disclosure, the second light blocking layer is made of a light blocking material.

In one embodiment of the present disclosure, the second light blocking layer is made of a black ink.

In one embodiment of the present disclosure, the second light blocking layer is in contact with the inner edge of the first light blocking layer and does not overlap the first light blocking layer.

In one embodiment of the present disclosure, the second light blocking layer overlaps with the inner edge of the first light blocking layer.

In one embodiment of the present disclosure, a width of the second light blocking layer is in a range of 0.5 mm to 1.5 mm.

In one embodiment of the present disclosure, a width of the second light blocking layer is 1 mm.

At least one embodiment of the present disclosure provides a display panel comprising the touch screen mentioned above.

At least one embodiment of the present disclosure provides a display device comprising the display panel mentioned above.

### BRIEF DESCRIPTION OF THE DRAWINGS

In order to clearly illustrate the technical solutions of the embodiments of the disclosure, the drawings of the embodiments will be briefly described in the following; it is obvious that the drawings described below are only related to some embodiments of the disclosure and thus are not limitative of the disclosure.

FIG. 1 is an illustrative structural view of a touch screen according to an embodiment of the present disclosure; and

FIG. 2 is an illustrative structural view of a touch screen according to another embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

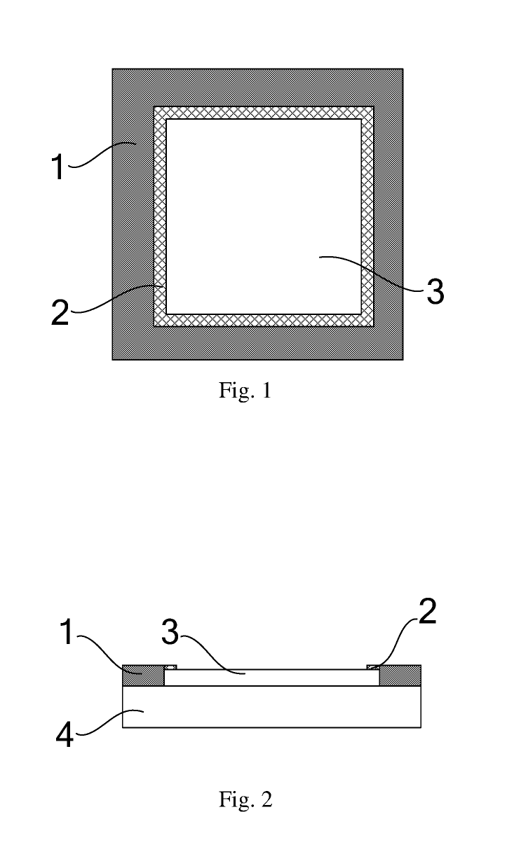

As illustrated in FIG. 1 and FIG. 2, a touch screen, comprising a base substrate 4 and further comprising a first light blocking layer 1, a touch layer 3 and a second light blocking layer 2, wherein

The first light blocking layer 1 is disposed on an edge of the base substrate 4;

The touch layer 3 is disposed on the base substrate 4, and the touch layer 3 is in contact with the inner edge of the first light blocking layer 1 and does not overlap with each other;

The second light blocking layer 2 is disposed on the touch layer 3, and the second light blocking layer 2 is in contact with the inner edge of the first light blocking layer 1.

In the touch screen mentioned above, as the touch layer 3 and the first light blocking layer 1 are disposed on the base substrate 4, the touch layer 3 is in contact with the inner edge of the first light blocking layer 1 and does not overlap with each other, and the second light blocking layer 2 is disposed on the touch layer 3, and the second light blocking layer 2 is in contact with the inner edge of the first light blocking layer 1, ensuring that there is no portion of the first light blocking layer 1 disposed below the touch layer 3, so as to avoid an electrostatic path formed due to breakdown of the first light blocking layer 1 during electrostatic test, thereby eliminating ESD.

Therefore, by removing the first light blocking layer 2 at the edge of the touch layer 3 overlapping the pattern, no electrostatic path will be formed during the electrostatic test and no electrostatic discharge will occur.

In an embodiment of the present disclosure, the first light blocking layer is a black light blocking layer.

In an embodiment of the present disclosure, material for the second light blocking layer 2 is a light blocking material.

In an embodiment of the present disclosure, material for the second light blocking layer 2 is black ink.

In designing a mask for the touch screen, the first light blocking layer 1 is extended outside in advance, and a blank region is formed between the visible area formed by the touch layer 3 after the photo process. In a later stage, the blank region is filled by blank ink through imprint so as to not form the first light blocking layer 1 under the edge of the pattern of the visual area.

The second light blocking layer 2 is made of a light blocking material which is configured to block light. Depending on the shape, the profile and the optical performance of the touch screen, the second light blocking layer 2 can be made of black ink, and can also be made of other material which meets the optical performance of the second light blocking layer 2.

In one embodiment of the present disclosure, the second light blocking layer 2 is in contact with the inner edge of the first light blocking layer 1 and does not overlap the first light blocking layer 1.

In order to ensure that patterns on the base substrate 4 are consecutive, the second light blocking layer 2 is in contact with the inner edge of the first light blocking layer 1 and does not overlap the first light blocking layer 1. Alternatively, the second light blocking layer 2 is in contact with the inner edge of the first light blocking layer, a portion of the second light blocking layer 2 does not cover the first light blocking layer 1, and the other portion of the second light blocking layer 2 is disposed on the first light blocking layer 1.

In one embodiment of the present disclosure, a width of the second light blocking layer 2 is in a range of 0.5 mm to 1.5 mm.

The width of the second light blocking layer 2 can be 0.5 mm, 0.6 mm, 0.7 mm, 0.8 mm, 0.9 mm, 1.0 mm, 1.1 mm, 1.2 mm, 1.3 mm, 1.4 mm, 1.5 mm, and etc.

For example, the width of the second light blocking layer 2 is 1 mm. The width of the second light blocking layer 2 can be selected depending on the shape and the profile of the touch screen and other requirements.

At least one embodiments of the present disclosure provide a display panel, comprising the touch screen mentioned above.

An electrostatic path is avoided to be formed due to breakdown of the first light blocking layer 1 in electrostatic test of the touch screen, and as a result, electrostatic discharge is avoided. Thus, there is no electrostatic discharge in the display panel comprising the touch screen mentioned above.

At least one embodiment of the present disclosure provides a display device, comprising the display panel mentioned above.

As there is no electrostatic discharge in the display panel mentioned above, there is no electrostatic discharge in the display device comprising the display panel mentioned above.

The foregoing are merely exemplary embodiments of the disclosure, but are not used to limit the protection scope of the disclosure. The protection scope of the disclosure shall be defined by the attached claims.

The present disclosure claims priority of Chinese Patent Application No. 201620945343.X filed on Aug. 25, 2016, the disclosure of which is hereby entirely incorporated by reference.

1. A touch screen, comprising a base substrate, a first light blocking layer, a touch layer and a second light blocking layer, wherein:
the touch layer is disposed on a central area of the base substrate;
the first light blocking layer is a black light blocking layer, and disposed on a periphery area of the base substrate, the first light blocking layer is contiguous with the touch layer and an orthographic projection of the first light blocking layer on the base substrate does not overlap an orthographic projection of the touch layer on the base substrate;
and
the second light blocking layer is disposed on the touch layer, and the second light blocking layer is contiguous with the first light blocking layer.

2. The touch screen according to claim 1, wherein the second light blocking layer comprises a light blocking material.

3. The touch screen according to claim 2, wherein the second light blocking layer comprises a black ink.

4. The touch screen according to claim 1, wherein an orthographic projection of the second light blocking layer on the base substrate does not overlap an orthographic projection of the first light blocking layer on the base substrate.

5. The touch screen according to claim 1, wherein an orthographic projection of the second light blocking layer on the base substrate overlaps an orthographic projection of the first light blocking layer on the base substrate.

6. The touch screen according to claim 1, wherein a width of the second light blocking layer is in a range of 0.5 mm to 1.5 mm.

7. The touch screen according to claim 1, wherein a width of the second light blocking layer is 1 mm.

8. A display panel, comprising the touch screen according to claim 1.

9. A display device, comprising the display panel according to claim 8.

10. The touch screen according to claim 2, wherein an orthographic projection of the second light blocking layer on the base substrate does not overlap an orthographic projection of the first light blocking layer on the base substrate.

11. The touch screen according to claim 3, wherein an orthographic projection of the second light blocking layer on the base substrate does not overlap an orthographic projection of the first light blocking layer on the base substrate.

12. The touch screen according to claim 2, wherein an orthographic projection of the second light blocking layer on the base substrate overlaps an orthographic projection of the first light blocking layer on the base substrate.

13. The touch screen according to claim 3, wherein an orthographic projection of the second light blocking layer on the base substrate overlaps an orthographic projection of the first light blocking layer on the base substrate.

14. The touch screen according to claim 4, wherein an orthographic projection of the second light blocking layer on the base substrate overlaps an orthographic projection of the first light blocking layer on the base substrate.

15. The touch screen according to claim 2, wherein a width of the second light blocking layer is in a range of 0.5 mm to 1.5 mm.

16. The touch screen according to claim 3, wherein a width of the second light blocking layer is in a range of 0.5 mm to 1.5 mm.

17. The touch screen according to claim 4, wherein a width of the second light blocking layer is in a range of 0.5 mm to 1.5 mm.

18. The touch screen according to claim 5, wherein a width of the second light blocking layer is in a range of 0.5 mm to 1.5 mm.

19. The touch screen according to claim 2, wherein a width of the second light blocking layer is 1 mm.

20. The touch screen according to claim 3, wherein a width of the second light blocking layer is 1 mm.
